(19) United States
(12) Patent Application Publication
(10) Pub. No.: US 2006/0091474 A1
(43) Pub. Date: May 4, 2006

(54) Semiconductor device and manufacturing method thereof

(76) Inventors: Toshihide Nabatame, Tsukuba (JP); Masaru Kadoshima, Tsukuba (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/260,188

(22) Filed: Oct. 28, 2005

(30) Foreign Application Priority Data
Oct. 29, 2004 (JP) JP2004-314896

(51) Int. Cl. H01L 29/76

(52) U.S. Cl. 257/371

(57) ABSTRACT

The manufacturing process of a semiconductor device in which a n channel MIS transistor and a p channel MIS transistor each having a gate electrode made of a metal material formed on a gate insulator made of a high dielectric constant material are used to form a CMOS circuit is simplified. After simultaneously forming the gate electrodes of the n channel MIS transistor and the p channel MIS transistor by patterning a platinum film deposited on a gate insulator made of a hafnium oxide film, only the gate insulator on the side of the n channel MIS transistor is selectively reduced by using the catalytic reduction of the platinum film. By doing so, the work function of the gate electrode of the n channel MIS transistor is changed.

### CROSS-REFERENCE TO RELATED APPLICATION

The present application claims priority from Japanese Patent Application No. JP 2004-314896 filed on Oct. 29, 2004, the content of which is hereby incorporated by reference into this application.

### TECHNICAL FIELD OF THE INVENTION

The present invention relates to a semiconductor device and a manufacturing method thereof. More particularly, it relates to a technology effectively applied to a semiconductor device in which a n channel MIS transistor and a p channel MIS transistor each having a metal gate electrode formed on a gate insulator made of a high dielectric constant material such as hafnium oxide are used to form a CMOS (Complementary Metal Oxide Semiconductor) circuit.

### BACKGROUND OF THE INVENTION

Conventionally, in the n channel MOS transistor and the p channel MOS transistor which constitute a CMOS circuit, a silicon oxide film is used as a gate insulator material, and a polycrystalline silicon film or a laminated film (polycide film) obtained by laminating a metal silicide film such as a tungsten silicide film or a cobalt silicide film on a polycrystalline silicon film is used as a gate electrode material formed on the gate oxide film.

However, along with the miniaturization of the MIS transistors constituting the semiconductor integrated circuit, the thickness of the gate oxide film has been rapidly reduced in recent years. Consequently, when voltage is applied to the gate electrode to turn on the MIS transistor, the influence of the depletion in the gate electrode (polycrystalline silicon film) adjacent to the gate oxide film interface becomes increasingly significant, and the thickness of the gate oxide film is apparently increased. As a result, it becomes difficult to ensure the ON current and the operation speed of the transistor is significantly reduced.

Also, when the thickness of the gate oxide film is reduced, since the electrons pass through the gate oxide film due to the quantum effect called direct tunneling, the leakage current is increased. Furthermore, in the p channel MIS transistor, boron in the gate electrode (polycrystalline silicon film) diffuses in the substrate through the gate oxide film, and the impurity concentration of the channel region is increased. Therefore, the threshold voltage fluctuates.

For its solution, the replacement of the gate insulator material from the silicon oxide to an insulating material with a higher dielectric constant (high dielectric constant material) and the replacement of the gate electrode material from the polycrystalline silicon (or polycide) to metal have been examined.

This is because, when the high dielectric constant film is used to constitute the gate insulator, the actual physical thickness can be increased by a factor of “dielectric constant of a high dielectric constant film/dielectric constant of a silicon oxide film” without changing the capacitance of the equivalent silicon oxide thickness (EOT), and as a result, the leakage current can be reduced. As a high dielectric constant material, various metal oxides such as hafnium oxide and zirconium oxide have been examined.

In addition, when a material not containing polycrystalline silicon is used to constitute the gate electrode, the reduction of the ON current due to the depletion and the boron leakage from the gate electrode to the substrate can be prevented.

Incidentally, the low power consumption design is important in the CMOS circuit, and the reduction of the threshold voltage of the n channel MIS transistor and the p channel MIS transistor is required for its achievement. Therefore, even when a high dielectric constant material such as hafnium oxide is used as a gate insulator material and metal is used as a gate electrode material, it is necessary to select gate electrode materials with a suitable work function so as to prevent the increase of the threshold voltage in the n channel MIS transistor and the p channel MIS transistor.

For example, Japanese Patent Application Laid-Open publication No. 2000-252370 (Patent Document 1) discloses a CMOS circuit in which zirconium or hafnium is used to constitute a gate electrode of a n channel MIS transistor, and platinum silicide, iridium silicide, cobalt, nickel, rhodium, palladium, rhenium, or gold is used to constitute a gate electrode of a p channel MIS transistor.

Also, Japanese Patent Application Laid-Open Publication No. 2004-165555 (Patent Document 2) discloses a CMOS circuit in which titanium, aluminum, tantalum, molybdenum, hafnium or niobium is used to constitute a gate electrode of a n channel MIS transistor, and tantalum nitride, ruthenium oxide, iridium, platinum, tungsten nitride or molybdenum nitride is used to constitute a gate electrode of a p channel MIS transistor.

Also, Japanese Patent Application Laid-Open Publication No. 2004-165346 (Patent Document 3) discloses a CMOS circuit in which aluminum is used to constitute a gate electrode of a n channel MIS transistor, and compound metal obtained by introducing metal with a work function larger than aluminum (for example, cobalt, nickel, ruthenium, iridium, platinum and others) into aluminum is used to constitute a gate electrode of a p channel MIS transistor.

### SUMMARY OF THE INVENTION

However, in the conventional technology in which the gate electrode of the n channel MIS transistor and the gate electrode of the p channel MIS transistor are made of different metal materials, the manufacturing process of the transistor becomes very complicated and the number of steps greatly increases.

An object of the present invention is to provide a technology capable of simplifying the manufacturing process of a semiconductor device in which a n channel MIS transistor and a p channel MIS transistor each having a gate electrode made of a metal material formed on a gate insulator made of a high dielectric constant material are used to form a CMOS circuit.

The above and other objects and novel characteristics of the present invention will be apparent from the description of this specification and the accompanying drawings.

The typical ones of the inventions disclosed in this application will be briefly described as follows.

A manufacturing method of a n channel MIS transistor and a p channel MIS transistor according to the present invention comprises the steps of: (a) forming a gate insulator mainly containing metal oxide on a main surface of a semiconductor substrate; (b) after forming a metal film mainly containing noble metal with catalytic reduction effect on the gate insulator, patterning the metal film, thereby forming a gate electrode of the n channel MIS transistor on the gate insulator in the first region and forming a gate electrode of the p channel MIS transistor on the gate insulator in the second region; (c) forming sidewall spacers on sidewalls of the gate electrode of the n channel MIS transistor and on sidewalls of the gate electrode of the p channel MIS transistor; (d) after the step (c), forming a diffusion barrier film, which prevents penetration of hydrogen into the gate electrode, on the gate electrode of the p channel MIS transistor; and (e) after the step (d), performing thermal treatment of the semiconductor substrate in an atmosphere containing hydrogen.

According to the method described above, hydrogen is penetrated and diffused into the gate electrode of the n channel MIS transistor exposed to high-temperature hydrogen atmosphere, and some of the hydrogen reaches the underlying gate insulator. At this time, due to the catalytic reduction of the metal constituting the gate electrode, a part of the gate insulator is reduced by the hydrogen. As a result, the composition of the gate insulator is changed and thus the work function of the gate electrode on the gate insulator is changed.

### BRIEF DESCRIPTIONS OF THE DRAWINGS

FIG. 1 is a cross-sectional view of a semiconductor substrate showing the manufacturing method of a n channel MIS transistor and a p channel MIS transistor according to an embodiment of the present invention;

FIG. 2 is a cross-sectional view of the semiconductor substrate showing the manufacturing method of the n channel MIS transistor and the p channel MIS transistor subsequent to FIG. 1;

FIG. 3 is a cross-sectional view of the semiconductor substrate showing the manufacturing method of the n channel MIS transistor and the p channel MIS transistor subsequent to FIG. 2;

FIG. 4 is a cross-sectional view of the semiconductor substrate showing the manufacturing method of the n channel MIS transistor and the p channel MIS transistor subsequent to FIG. 3;

FIG. 5 is a cross-sectional view of the semiconductor substrate showing the manufacturing method of the n channel MIS transistor and the p channel MIS transistor subsequent to FIG. 4;

FIG. 6 is a cross-sectional view of the semiconductor substrate showing the manufacturing method of the n channel MIS transistor and the p channel MIS transistor subsequent to FIG. 5;

FIG. 7 is a cross-sectional view of the semiconductor substrate showing the manufacturing method of the n channel MIS transistor and the p channel MIS transistor subsequent to FIG. 6;

FIG. 8 is a cross-sectional view of the semiconductor substrate showing the manufacturing method of the n channel MIS transistor and the p channel MIS transistor subsequent to FIG. 7;

FIG. 9 is a graph showing the change in work function with using the flat band voltage in the case where a gate electrode made of a platinum film is formed on a gate insulator composed of a laminated film of a silicon oxide film and a hafnium oxide film, and this gate electrode is thermally treated in high-temperature gas atmosphere;

FIG. 10 is a cross-sectional view of the semiconductor substrate showing the manufacturing method of the n channel MIS transistor and the p channel MIS transistor subsequent to FIG. 8;

FIG. 11 is a cross-sectional view of the semiconductor substrate showing the manufacturing method of the n channel MIS transistor and the p channel MIS transistor subsequent to FIG. 10;

FIG. 12 is a cross-sectional view of the semiconductor substrate showing the manufacturing method of the n channel MIS transistor and the p channel MIS transistor subsequent to FIG. 11;

FIG. 13 is a cross-sectional view of a semiconductor substrate showing the manufacturing method of a n channel MIS transistor and a p channel MIS transistor according to another embodiment of the present invention;

FIG. 14 is a cross-sectional view of the semiconductor substrate showing the manufacturing method of the n channel MIS transistor and the p channel MIS transistor subsequent to FIG. 13;

FIG. 15 is a cross-sectional view of the semiconductor substrate showing the manufacturing method of the n channel MIS transistor and the p channel MIS transistor subsequent to FIG. 14;

FIG. 16 is a cross-sectional view of the semiconductor substrate showing the manufacturing method of the n channel MIS transistor and the p channel MIS transistor subsequent to FIG. 15;

FIG. 17 is a cross-sectional view of the semiconductor substrate showing the manufacturing method of the n channel MIS transistor and the p channel MIS transistor subsequent to FIG. 16;

FIG. 18 is a cross-sectional view of the semiconductor substrate showing the manufacturing method of the n channel MIS transistor and the p channel MIS transistor subsequent to FIG. 17;

FIG. 19 is a cross-sectional view of the semiconductor substrate showing the manufacturing method of the n channel MIS transistor and the p channel MIS transistor subsequent to FIG. 18;

FIG. 20 is a cross-sectional view of the semiconductor substrate showing the manufacturing method of the n channel MIS transistor and the p channel MIS transistor subsequent to FIG. 19; and

FIG. 21 is a cross-sectional view of the semiconductor substrate showing the manufacturing method of the n channel MIS transistor and the p channel MIS transistor subsequent to FIG. 20.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be omitted.

(First Embodiment)

The manufacturing method of a n channel MIS transistor and a p channel MIS transistor according to the first embodiment will be described with reference to FIG. 1 to FIG. 12.

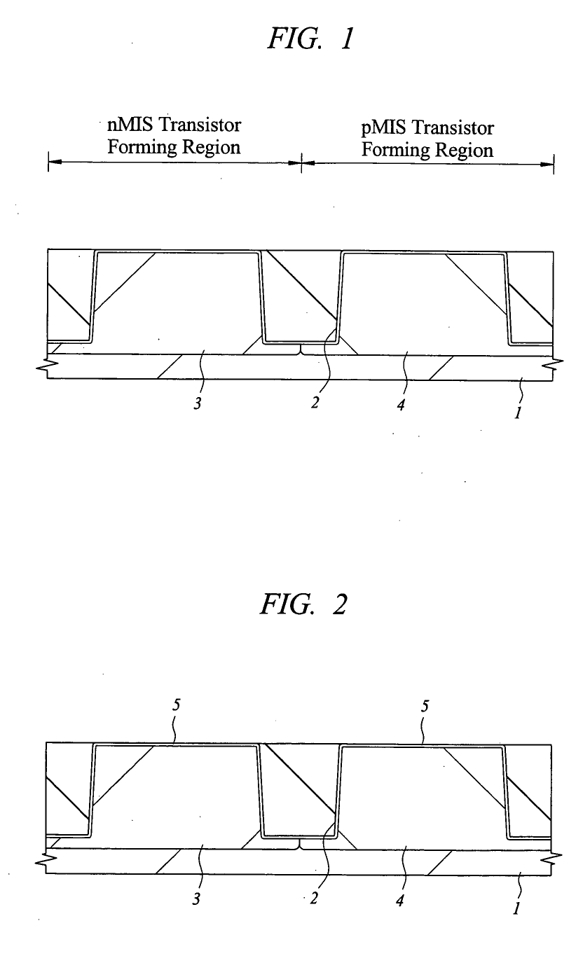

First, as shown in FIG. 1, a device isolation trench 2 is formed in the main surface of the semiconductor substrate (hereinafter, referred to as substrate) 1 made of p type single crystal silicon by using the well-known STI (Shallow Trench Isolation) technology. Thereafter, boron is ion-implanted into a n channel MIS transistor forming region (left side of FIG. 1) of the substrate 1, and phosphorus is ion-implanted into a p channel MIS transistor forming region (right side of FIG. 2) of the substrate 1. Subsequently, the impurities (boron and phosphorus) are diffused in the substrate 1 by the thermal treatment of the substrate 1, thereby forming a p type well 3 and a n type well 4 in the main surface of the substrate 1.

Next, impurities for adjusting the threshold voltage of the MIS transistors are ion-implanted into the respective surfaces of the p type well 3 and the n type well 4. Thereafter, as shown in FIG. 2, a gate insulator 5 made of hafnium oxide is formed on each of the surfaces of the p type well 3 and the n type well 4. The hafnium oxide film is deposited by the CVD or the ALD (Atomic Layer Deposition), and the thickness thereof is about 1.5 nm to 4.0 nm.

Note that it is also preferable to form a gate insulator composed of a laminated film of a silicon oxide film and a hafnium oxide film by depositing the hafnium oxide film on the silicon oxide film in the same manner as described above after forming the thin silicon oxide film with a thickness of about 0.4 nm to 1.5 nm on the surface of the substrate 1 by using the well-known wet oxidation method. In this case, it is also preferable to form a gate insulator by introducing nitrogen into the underlying silicon oxide film to form a silicon oxynitride film and then laminating a hafnium oxide film thereon.

In this embodiment, the gate insulator 5 is composed of a hafnium oxide film or a laminated film of a silicon oxide film and a hafnium oxide film. Alternatively, a hafnium-based insulator other than the hafnium oxide film, for example, Hf—Si—O film, Hf—Si—O—N film, Hf—Al—O film and Hf—Al—O—N film is also available. In addition, it is also possible to use a hafnium-based insulator obtained by introducing oxide such as tantalum oxide, niobium oxide, titanium oxide, zirconium oxide, lanthanum oxide, yttrium oxide and the like into these hafnium-based insulators. Similar to a hafnium oxide film, these hafnium-based insulators have a dielectric constant higher than that of a silicon oxide film and a silicon oxynitride film. Therefore, it is possible to obtain the effect equivalent to the case using a hafnium oxide film. These hafnium-based insulators can be deposited by the CVD, ALD, or sputtering method.

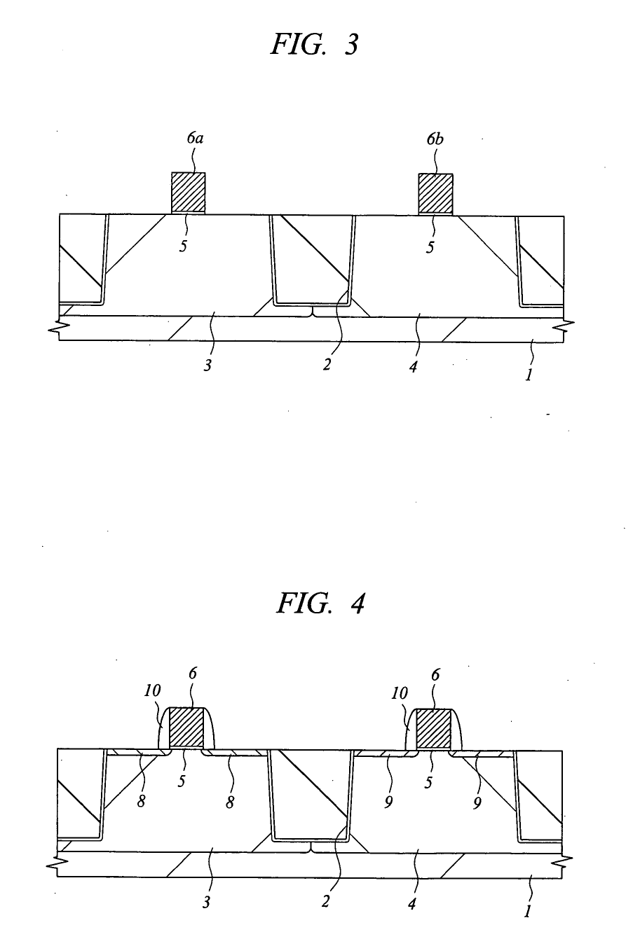

Next, as shown in FIG. 3, after depositing a platinum film by using the sputtering method on the substrate 1, this platinum film is patterned by the dry etching using a photoresist film (not shown) as a mask. By doing so, gate electrodes 6 made of the platinum film are formed on each of the gate insulators 5 of the p type well 3 and the n type well 4.

Next, as shown in FIG. 4, phosphorus or arsenic is ion-implanted into the p type well 3 to form n⁻ type semiconductor regions 8, and boron is ion-implanted into the n type well 3 to form p⁻ type semiconductor regions 9. Thereafter, sidewall spacers 10 are formed on each sidewall of the gate electrodes 6. The n⁻ type semiconductor regions 8 are formed in order to form the LDD (Lightly Doped Drain) structure in the n channel MIS transistor. Similarly, the p⁻ type semiconductor regions 9 are formed in order to form the LDD structure in the p channel MIS transistor. The sidewall spacer 10 is formed by depositing a silicon oxide film on the substrate 1 by the CVD and then performing the anisotropic etching of the silicon oxide film.

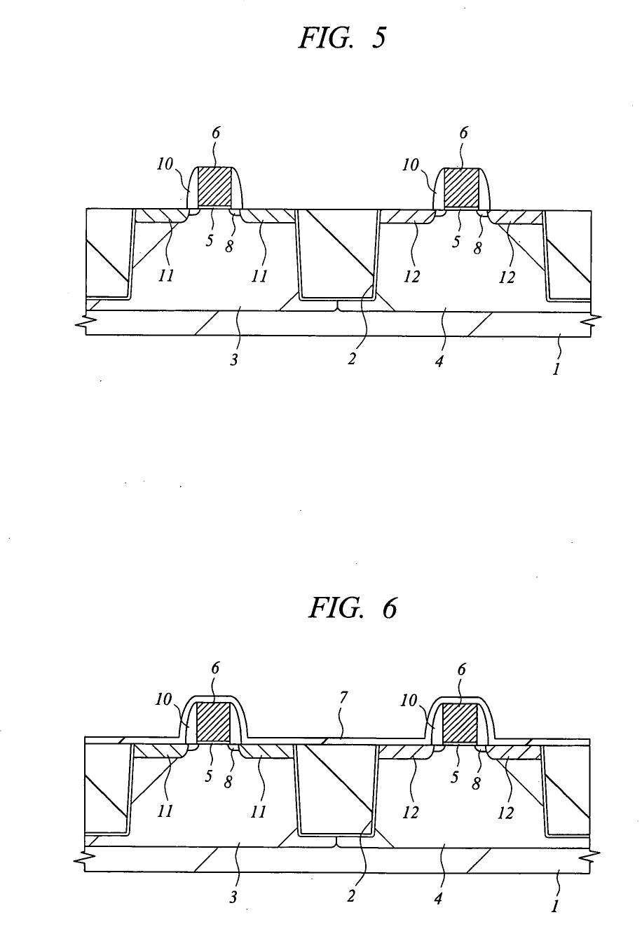

Next, as shown in FIG. 5, phosphorus or arsenic is ion-implanted into the p type well 3 and boron is ion-implanted into the n type well 3. Thereafter, the impurities are diffused by the thermal treatment of the substrate 1, thereby forming n⁺ type semiconductor regions (source, drain) 11 in the p type well 3 and forming p⁺ type semiconductor regions (source, drain) 12 in the n type well 4.

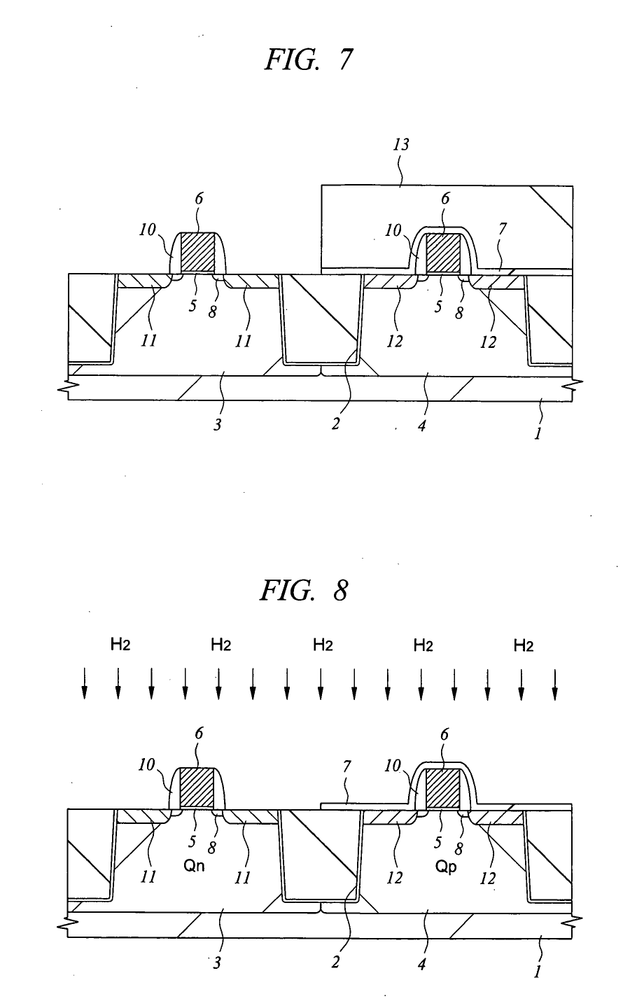

Next, as shown in FIG. 6, after depositing an alumina (Al₂O₃) film (diffusion barrier film) 7 on the substrate 1 by the sputtering method, the n type well 4 is covered with a photoresist film 13 and the alumina film 7 on the p type well 3 is removed by the dry etching as shown in FIG. 7. The alumina film left on the n type well 4 functions as a diffusion barrier film which prevents the penetration of hydrogen into the gate electrode 6 (platinum film) of the p channel MIS transistor formed below it, and the thickness thereof is desirably 10 nm or more.

Next, after removing the photoresist film 13, the substrate 1 is thermally treated in the high-temperature hydrogen atmosphere as shown in FIG. 8. The temperature of this thermal treatment is at least 400° C. or higher, more preferably, 450° C. or higher.

By the thermal treatment, the hydrogen is penetrated and diffused in the gate electrode 6 of the n channel MIS transistor exposed to the high-temperature hydrogen atmosphere, and some of the hydrogen reaches the gate insulator 5 below the gate electrode 6. At this time, due to the catalytic reduction of platinum constituting the gate electrode 6, a part of hafnium oxide constituting the gate insulator 5 is reduced by the hydrogen into the oxygen-deficient hafnium oxide. Furthermore, as a result of the reaction with the silicon constituting the substrate 1, a part of hafnium oxide constituting the gate insulator 5 is changed into Hf—Si—O in some cases. On the other hand, since the hydrogen is little penetrated into the gate electrode 6 of the p channel MIS transistor covered with the alumina film 7, the composition of the hafnium oxide constituting the underlying gate insulator 5 is not changed.

Through the process described above, the n channel MIS transistor (Qn) is formed on the p type well 3 and the p channel MIS transistor (Qp) is formed on the n type well 4.

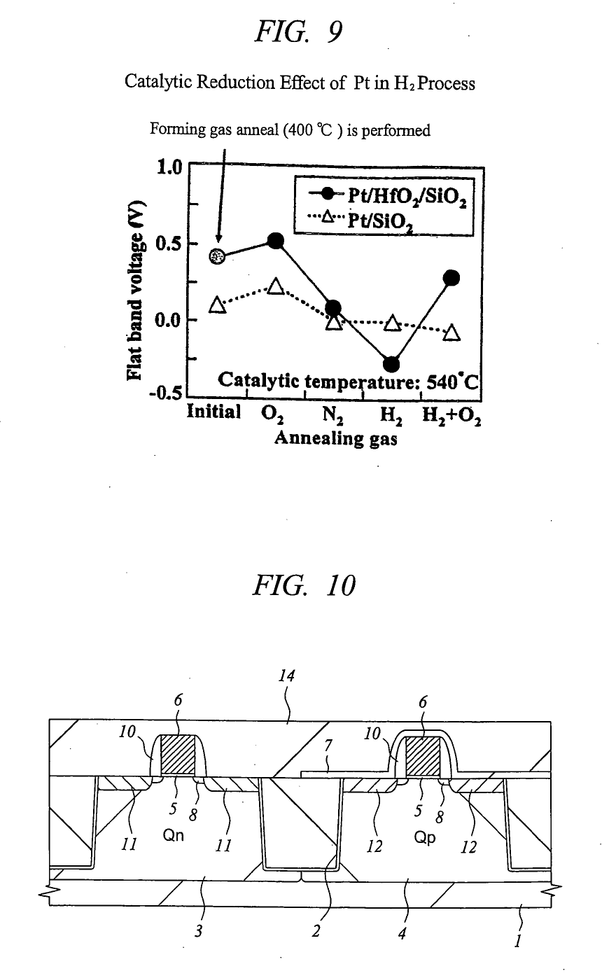

FIG. 9 is a graph showing the change in work function with using the flat band voltage in the case where a gate electrode made of a platinum film is formed on a gate insulator composed of a laminated film of a silicon oxide film and a hafnium oxide film, and this gate electrode is thermally treated in high-temperature gas atmosphere. Four types of gas such as oxygen, nitrogen, hydrogen and mixed gas of hydrogen and oxygen are used here. Also, the temperature of the thermal treatment is set at 540° C.

As shown in the graph, when the thermal treatment is performed in the hydrogen atmosphere, the flat band voltage of the gate electrode significantly shifts in the negative voltage direction. As described above, the change in flat band like this is caused by the change in composition of the gate insulator 5 in the oxygen-deficient direction resulting from the hydrogen reduction of a part of the gate insulator 5 (hafnium oxide film) due to the catalytic reduction of the gate electrode 6 (platinum film). Meanwhile, in the case of the thermal treatment in the gas atmosphere other than hydrogen, since the catalytic reduction cannot be expected, the change in work function is small. Also, in the case where the thermal treatment is performed in the high-temperature hydrogen atmosphere to the gate electrode made of a platinum film formed on the gate insulator made of a silicon oxide film, the change in work function is extremely small. This is because the silicon oxide film is not readily reduced by hydrogen.

Then, the platinum film deposited on the gate insulator 5 made of a hafnium oxide film as described above is patterned. By doing so, the gate electrodes 6 of each of the n channel MIS transistor (Qn) and the p channel MIS transistor (Qp) are simultaneously formed. Thereafter, only the gate electrode 6 of the n channel MIS transistor (Qn) is selectively exposed to the high-temperature hydrogen atmosphere. Consequently, the work function of the gate electrode 6 of the n channel MIS transistor (Qn) can be greatly reduced.

More specifically, the work functions of the transistors can be optimized in a smaller number of manufacturing steps than that of the case where the gate electrode of the n channel MIS transistor (Qn) and the gate electrode of the p channel MIS transistor (Qp) are formed of the different metal materials. Therefore, since it is possible to reduce the threshold voltage of the respective transistors while reducing the number of manufacturing steps, the CMOS circuit capable of simultaneously achieving the high ON current and the low power consumption can be realized at low cost.

As the metal material with catalytic reduction effect and capable of optimizing the work function of the gate electrodes of the n channel MIS transistor (Qn) and the p channel MIS transistor (Qp), iridium and palladium can be exemplified in addition to the above-mentioned platinum. Also, as a material of the diffusion barrier film which prevents the penetration of hydrogen into the gate electrode, compound metal oxide obtained by bonding metal or metal oxide to alumina as a main substance and tantalum oxide can be exemplified in addition to the above-mentioned alumina.

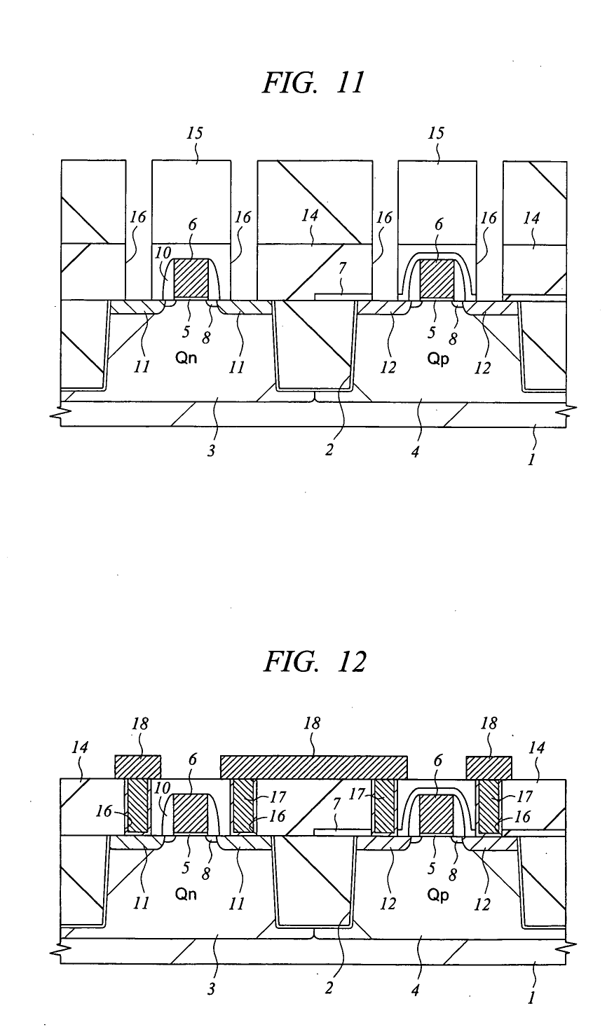

Next, as shown in FIG. 10, after depositing a silicon oxide film 14 on the substrate 1 by the CVD, the silicon oxide film 14 and the alumina film 7 are dry-etched with using a photoresist film 15 as a mask as shown in FIG. 11. By doing so, contact holes 16 are formed on the n⁺ type semiconductor regions (source, drain) 11 and the p⁺ type semiconductor regions (source, drain) 12.

Subsequently, after removing the photoresist film 15, as shown in FIG. 12, plugs 17 are formed in the contact holes 16, and then, metal wirings 18 are formed on the silicon oxide film 14. The plugs 17 are formed by depositing a titanium nitride (TiN) film and a tungsten (W) film on the silicon oxide film 14 and in the contact holes 16 by the sputtering method, and then, removing the TiN film and the W film on the silicon oxide film 14 by the CVD. Also, the metal wiring 18 is formed by depositing a metal film such as a W film or an Al alloy film on the silicon oxide film 14 by the sputtering method, and then, patterning the metal film by the dry etching using a photoresist film (not shown) as a mask. Through the process described above, the CMOS circuit comprising the n channel MIS transistor (Qn) and the p channel MIS transistor (Qp) is almost completed.

(Second Embodiment)

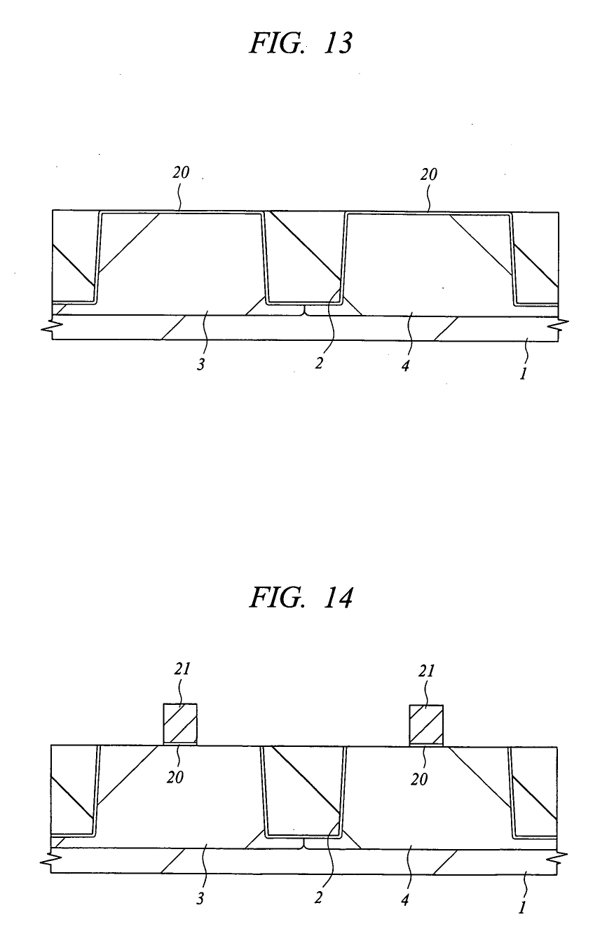

The manufacturing method of a n channel MIS transistor (Qn) and a p channel MIS transistor (Qp) according to the second embodiment will be described with reference to FIG. 13 to FIG. 21.

First, by the same method as described in the first embodiment with reference to FIG. 1, the device isolation trenches 2, the p type well 3 and the n type well 4 are formed in the main surface of the substrate 1. Subsequently, impurities for adjusting the threshold voltage of the MIS transistors are ion-implanted into the surfaces of the p type well 3 and the n type well 4. Next, as shown in FIG. 13, a silicon oxide film 20 is formed on each of the surfaces of the p type well 3 and the n type well 4 by the thermal treatment of the substrate 1.

Next, as shown in FIG. 14, after depositing a polycrystalline silicon film (or amorphous silicon film) on the substrate 1 by the CVD, the polycrystalline silicon film is patterned by the dry etching using a photoresist film (not shown) as a mask. By doing so, a silicon gate electrode 21 is formed on each of the silicon oxide films 20 of the p type well 3 and the n type well 4. The silicon gate electrodes 21 are dummy gate electrodes to be removed from the substrate 1 in the process described later. Therefore, the material thereof is not limited to silicon, and various kinds of insulating materials and metal materials with the high etching selectivity to the silicon oxide based insulator can be used.

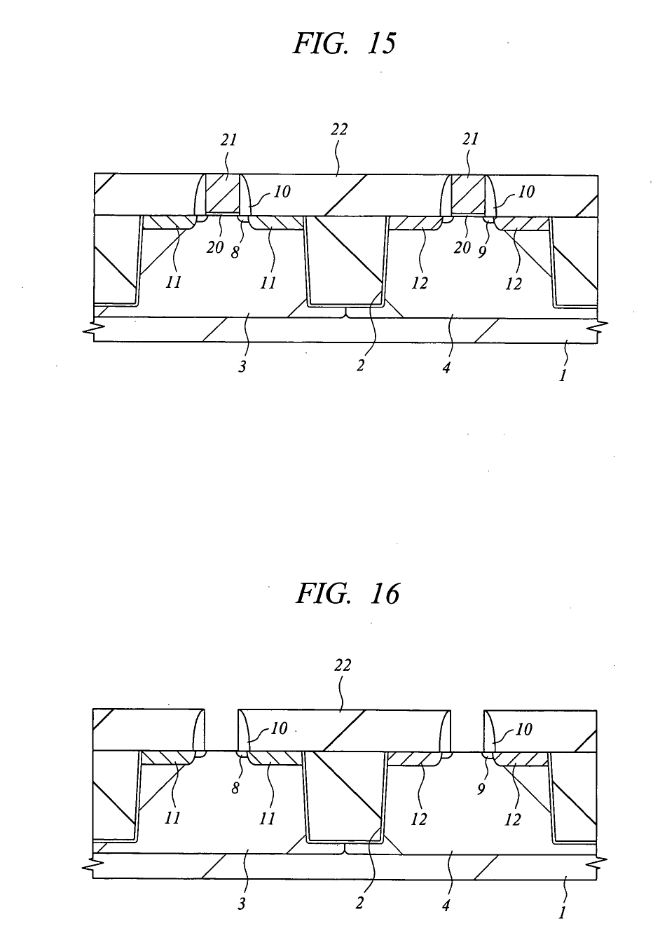

Next, as shown in FIG. 15, the n type semiconductor regions 8, the p⁻ type semiconductor regions 9, the sidewall spacers 10, the n⁺ type semiconductor regions (source, drain) 11 and the p⁺ type semiconductor regions (source, drain) 12 are sequentially formed through the same process as described in the first embodiment with reference to FIG. 4 and FIG. 5. Subsequently, after depositing a silicon oxide film 22 on the substrate 1 by the CVD, the surface of the silicon oxide film 22 is polished and planarized by the CMP. By doing so, the upper surfaces of the silicon gate electrodes 21 are exposed on the surface of the silicon oxide film 22.

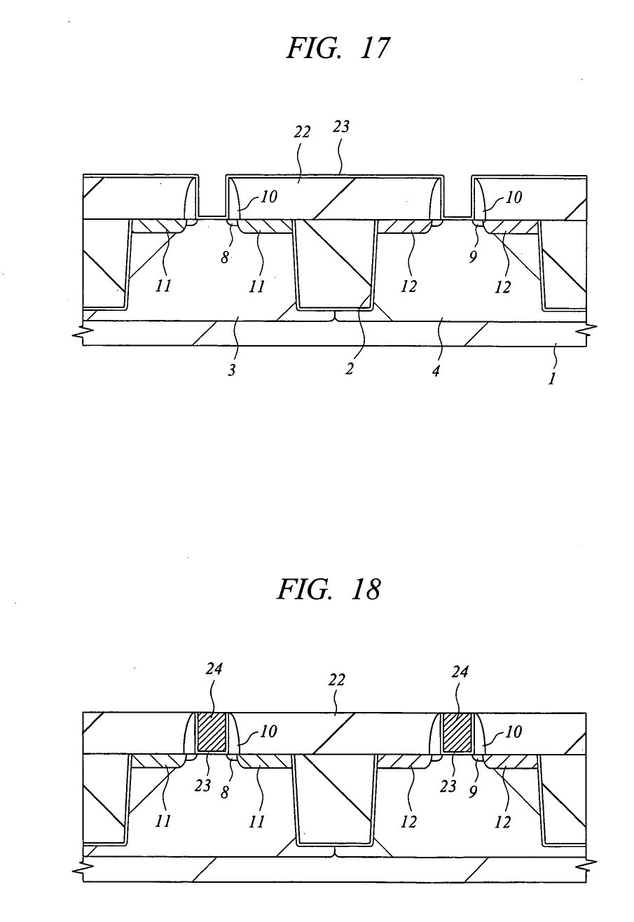

Next, as shown in FIG. 16, the silicon gate electrodes 21 and the underlying silicon oxide film 20 are etched and removed to expose the surface of the substrate 1 (p type well 3, n type well 4). Thereafter, as shown in FIG. 17, a gate insulator 23 is formed on the substrate 1. Any one of various kinds of hafnium-based insulating materials exemplified in the first embodiment is used for the gate insulator 23, and the gate insulator 23 is deposited by the CVD, the ALD, or the sputtering method so as to have a small thickness which does not fill the inside of the trenches formed by the removal of the silicon gate electrodes 21 and the silicon oxide film 20.

Next, as shown in FIG. 18, after depositing a platinum film on the substrate 1 by the sputtering method, the platinum film and the gate insulator 23 on the silicon oxide film 22 are polished and removed by the CVD. By doing so, a gate electrode 24 made of the platinum film is formed on the gate insulator 23 of the p type well 3 and a gate electrode 24 made of the platinum film is formed on the gate insulator 23 of the n type well 4.

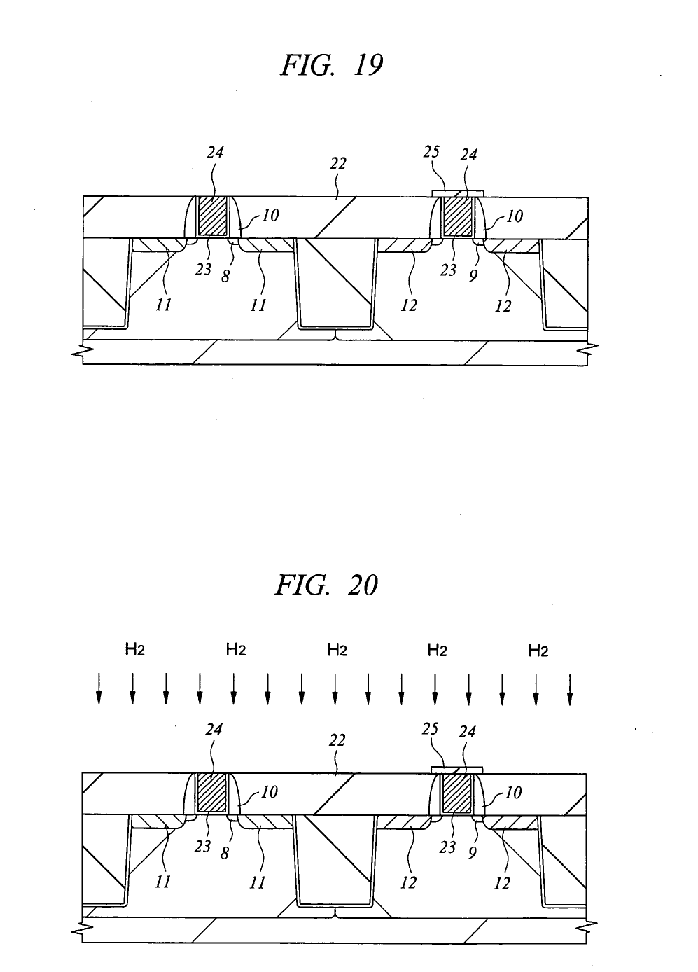

Next, as shown in FIG. 19, after depositing an alumina film (diffusion barrier film) 25 on the substrate 1 by the sputtering method, the alumina film 25 is patterned by the dry etching using a photoresist film (not shown) as a mask to leave the alumina film 25 only on the gate electrode 24 on the side of the n type well 4. At this time, the upper surface of the gate electrode 24 on the side of the p type well 3 is exposed on the surface of the silicon oxide film 22.

Next, as shown in FIG. 20, the substrate 1 is thermally treated in the high-temperature hydrogen atmosphere. The temperature of this thermal treatment is at least 400° C. or higher, more preferably, 450° C. or higher. By the thermal treatment, the hydrogen is penetrated and diffused in the gate electrode 24 of the n channel MIS transistor exposed to the high-temperature hydrogen atmosphere, and some of the hydrogen reaches the gate insulator 23 below the gate electrode 24. Therefore, due to the catalytic reduction of platinum constituting the gate electrode 24, a part of the gate insulator 23 is reduced by the hydrogen. Consequently, the work function of the gate electrode 24 of the n channel MIS transistor formed on the gate insulator 23 is changed and the effect similar to that of the first embodiment can be realized.

Through the process described above, the n channel MIS transistor (Qn) is formed on the p type well 3 and the p channel MIS transistor (Qp) is formed on the n type well 4.

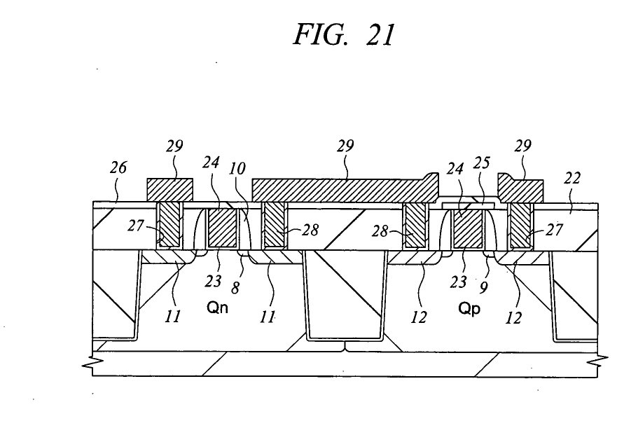

Next, as shown in FIG. 21, after depositing a silicon oxide film 26 on the substrate 1 by the CVD, contact holes 27, plugs 28 and metal wirings 29 are formed in the same manner as described in the first embodiment with reference to FIG. 11 and FIG. 12. Through the process described above, the CMOS circuit comprising the n channel MIS transistor (Qn) and the p channel MIS transistor (Qp) is almost completed.

According to the manufacturing method of the second embodiment, the gate insulator 23 is formed in the step immediately before the step of forming the gate electrodes 24. Therefore, it is possible to prevent the contamination and degradation of the gate insulator 23. As a result, the reliability of the n channel MIS transistor and the p channel MIS transistor can be improved.

In the foregoing, the invention made by the inventors of the present invention has been concretely described based on the embodiments. However, it is needless to say that the present invention is not limited to the foregoing embodiments and various modifications and alterations can be made within the scope of the present invention.

The present invention can be applied to the semiconductor device in which a n channel MIS transistor and a p channel MIS transistor each having a metal gate electrode formed on a gate insulator made of a high dielectric constant material such as hafnium oxide are used to form a CMOS circuit.

The effect obtained by the representative one of the inventions disclosed in this application will be briefly described as follows.

It is possible to simplify the manufacturing process of a semiconductor device in which a n channel MIS transistor and a p channel MIS transistor each having a gate electrode made of a metal material formed on a gate insulator made of a high dielectric constant material are used to form a CMOS circuit.

As a result, it is possible to reduce the threshold voltage in each of the n channel MIS transistor and the p channel MIS transistor in a small number of manufacturing steps. Therefore, the CMOS circuit capable of simultaneously achieving the high ON current and the low power consumption can be realized at low cost.

What is claimed is:

1. A semiconductor device in which a n channel MIS transistor is formed in a first region on a main surface of a semiconductor substrate made of single crystal silicon and a p channel MIS transistor is formed in a second region on said main surface,
wherein each of said n channel MIS transistor and said p channel MIS transistor comprises a gate electrode mainly containing noble metal with catalytic reduction effect formed on a gate insulator mainly containing metal oxide, and
a diffusion barrier film which prevents penetration of hydrogen into said gate electrode is formed on said gate electrode of said p channel MIS transistor.

2. The semiconductor device according to claim 1,
wherein said diffusion barrier film mainly contains alumina.

3. The semiconductor device according to claim 1,
wherein said noble metal with catalytic reduction effect is platinum, iridium or palladium.

4. The semiconductor device according to claim 3,
wherein said noble metal with catalytic reduction effect is platinum.

5. The semiconductor device according to claim 1,
wherein said gate insulator mainly contains at least one of hafnium oxides selected from a group including HfO, Hf—Si—O, Hf—Si—O—N, Hf—Al—O and Hf—Al—O—N.

6. A manufacturing method of a semiconductor device in which a n channel MIS transistor is formed in a first region on a main surface of a semiconductor substrate made of single crystal silicon and a p channel MIS transistor is formed in a second region on said main surface, said method comprising the steps of:
(a) forming a gate insulator mainly containing metal oxide on the main surface of said semiconductor substrate;
(b) after forming a metal film mainly containing noble metal with catalytic reduction effect on said gate insulator, patterning said metal film, thereby forming a gate electrode of said n channel MIS transistor on said gate insulator in said first region and forming a gate electrode of said p channel MIS transistor on said gate insulator in said second region;
(c) forming sidewall spacers on sidewalls of the gate electrode of said n channel MIS transistor and on sidewalls of the gate electrode of said p channel MIS transistor;
(d) after said step (c), forming a diffusion barrier film, which prevents penetration of hydrogen into said gate electrode, on the gate electrode of said p channel MIS transistor; and
(e) after said step (d), performing thermal treatment of said semiconductor substrate in an atmosphere containing hydrogen.

7. The manufacturing method of a semiconductor device according to claim 6,
wherein said diffusion barrier film mainly contains alumina.

8. The manufacturing method of a semiconductor device according to claim 6,
wherein said noble metal with catalytic reduction effect is platinum, iridium or palladium.

9. The manufacturing method of a semiconductor device according to claim 8,
wherein said noble metal with catalytic reduction effect is platinum.

10. The manufacturing method of a semiconductor device according to claim 6,
wherein said gate insulator mainly contains at least one of hafnium oxides selected from a group including HfO, Hf—Si—O, Hf—Si—O—N, Hf—Al—O and Hf—Al—O—N.

11. The manufacturing method of a semiconductor device according to claim 6,
wherein temperature of said thermal treatment in said step (e) is 450° C. or higher.

12. A manufacturing method of a semiconductor device in which a n channel MIS transistor is formed in a first region on a main surface of a semiconductor substrate made of single crystal silicon and a p channel MIS transistor is formed in a second region on said main surface, said method comprising the steps of:
(a) forming a first dummy gate electrode of said n channel MIS transistor in said first region on the main surface of said semiconductor substrate and forming a second dummy gate electrode of said p channel MIS transistor in said second region;
(b) forming sidewall spacers on sidewalls of said first and second dummy gate electrodes;
(c) after said step (b), depositing a first insulator with a thickness larger than said first and second dummy gate electrodes on the main surface of said semiconductor substrate, and then, planarizing a surface of said first insulator, thereby exposing each surface of said first and second dummy gate electrodes on the surface of said first insulator;
(d) after said step (c), removing said first and second dummy gate electrodes, thereby exposing the surface of said semiconductor substrate below said first and second dummy gate electrodes;
(e) forming a gate insulator mainly containing metal oxide on the surface of said semiconductor substrate exposed in said step (d);
(f) forming a metal film mainly containing noble metal with catalytic reduction effect on said gate insulator, and then, patterning said metal film, thereby forming a gate electrode of said n channel MIS transistor on said gate insulator in said first region and forming a gate electrode of said p channel MIS transistor on said gate insulator in said second region;
(g) forming a diffusion barrier film, which prevents penetration of hydrogen into said gate electrode, on the gate electrode of said p channel MIS transistor; and
(h) after said step (g), performing thermal treatment of said semiconductor substrate in an atmosphere containing hydrogen.

13. The manufacturing method of a semiconductor device according to claim 12,
wherein said diffusion barrier film mainly contains alumina.

14. The manufacturing method of a semiconductor device according to claim 12,
wherein said noble metal with catalytic reduction effect is platinum, iridium or palladium.

15. The manufacturing method of a semiconductor device according to claim 14,
wherein said noble metal with catalytic reduction effect is platinum.

16. The manufacturing method of a semiconductor device according to claim 12,
wherein said gate insulator mainly contains at least one of hafnium oxides selected from a group including HfO, Hf—Si—O, Hf—Si—O—N, Hf—Al—O and Hf—Al—O—N.

17. The manufacturing method of a semiconductor device according to claim 12,
wherein temperature of said thermal treatment in said step (h) is 450° C. or higher.
